(19) United States
(12) Patent Application Publication
(10) Pub. No.: US 2009/0017248 A1
(43) Pub. Date: Jan. 15, 2009

(54) LAYERED BODY AND METHOD FOR MANUFACTURING THIN SUBSTRATE USING THE LAYERED BODY

(75) Inventors: Eric G. Larson, Lake Elmo, MN (US); Richard J. Webb, Inver Grove Heights, MN (US); Michael A. Kropp, Cottage Grove, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 12/201,289

(22) Filed: Aug. 29, 2008

Related U.S. Application Data
(63) Continuation-in-part of application No. 11/777,328, filed on Jul. 13, 2007.

(51) Int. Cl. B32B 27/18; B32B 37/00; B32B 7/10; H01L 21/00; H01L 51/40

(52) U.S. Cl. 428/41.5; 427/150; 438/99; 438/113; 257/E21.001; 257/E51.001

(57) ABSTRACT

Provided is a layered body including a substrate to be ground and a support, where the substrate may be ground to a very small (thin) thickness and can then be separated from the support without damaging the substrate. One embodiment is a layered body including a substrate to be ground, a joining layer having a curable acrylate polymer and a curable acrylate adhesion modifying agent in contact with the substrate to be ground, a photothermal conversion layer having a light absorbing agent and a heat decomposable resin, and a light transmitting support. After grinding the substrate surface which is opposite that in contact with the joining layer, the layered body is irradiated through the light transmitting layer and the photothermal conversion layer decomposes to separate the substrate and the light transmitting support.

### CROSS REFERENCE TO RELATED APPLICATIONS

This application is a continuation-in-part of U.S. Application Ser. No. 11/777,328 filed on Jul. 13, 2007, which is hereby incorporated by reference in its entirety.

### TECHNICAL FIELD

The present disclosure relates to a layered body where a substrate to be ground, such as silicon wafer, fixed on a support can be easily separated from the support even after carrying out processes on the substrate that require elevated temperatures for extended periods, and also relates to a method for manufacturing this layered body and a method for producing a thinned substrate.

### BACKGROUND

In various fields, reducing the thickness of a substrate often is critical. For example, in the field of quartz devices, reducing the thickness of a quartz wafer is desired so as to increase the oscillation frequency. Particularly, in the semiconductor industry, efforts to further reduce the thickness of a semiconductor wafer are in progress to respond to the goal of reducing the thickness of semiconductor packages as well as for high-density fabrication by chip lamination technology. Thickness reduction is performed by so-called back side grinding of a semiconductor wafer on the surface opposite that containing pattern-formed circuitry. Usually, in conventional techniques of grinding the back side, or surface, of a wafer and conveying it while holding the wafer with only a backgrinding protective tape, thickness reduction can be accomplished in practice only to a thickness of about 150 micrometers (μm) because of problems such as uneven thickness of the ground wafer or warping of the wafer with protective tape after grinding. For example, Japanese Unexamined Patent Publication (Kokai) No. 6-302569 discloses a method where a wafer is held on a ring-form frame through a pressure-sensitive acrylate adhesive tape, the back surface of this wafer held on the frame is ground and the wafer is conveyed to the next step. However, this method has not yet attained a remarkable improvement over the present level of wafer thickness that may be obtained without encountering the aforementioned problems of unevenness or warping.

A method of grinding the back surface of a wafer and conveying it while firmly fixing the wafer on a hard support through an acrylate adhesive agent has also been proposed. This tends to prevent the breakage of a wafer during the back surface grinding and conveyance by supporting the wafer using such a support. According to this method, a wafer can be processed to a lower thickness level as compared with the above-described method, however, the thin wafer cannot be separated from the support without breaking the wafer and therefore, this method may be practically used as a method of thinning a semiconductor wafer.

### SUMMARY OF THE DISCLOSURE

The present disclosure provides a layered body in which a substrate to be ground is fixed on a support, by means of an acrylate adhesive joining layer comprising a curable acrylate polymer and a curable acrylate adhesion modifying agent, and the joining layer can be easily peeled off from the substrate after grinding and processing steps that require elevated temperatures. The present disclosure further provides a method for manufacturing the layered body and a method for manufacturing a thin substrate using the layered body. In some preferred embodiments, the thin substrate may comprise a semiconductor wafer.

In one embodiment of the present disclosure, a layered body is provided. The layered body comprises a substrate to be ground; a joining layer comprising a curable acrylate polymer and a curable acrylate adhesion modifying agent in contact with the substrate to be ground; a photothermal conversion layer comprising a light absorbing agent and a heat decomposable resin; and a light transmitting support. After grinding the substrate surface that is opposite the surface that is in contact with the joining layer, the layered body can be irradiated through the light-transmitting support to decompose the photothermal conversion layer and to separate the substrate and the light transmitting support. In this layered body, the substrate that has been ground to a very small thickness can be separated from the support without breaking the substrate.

A method for manufacturing the above-described layered body is also provided. The method comprises the steps of: providing a photothermal conversion layer on a light transmitting support, applying a joining layer to a substrate to be ground or to the photothermal conversion layer, joining the substrate to be ground and the photothermal conversion layer by means of the joining layer, under reduced pressure, and curing the joining layer to form a layered body. The photothermal conversion layer may be provided by providing a photothermal conversion layer precursor containing a light absorbing agent and a heat decomposable resin solution, or a monomer or oligomer as a precursor material of a heat decomposable resin; and drying to solidify or cure the photothermal conversion layer precursor to form a photothermal conversion layer on the light transmitting support.

By joining the substrate to be ground and the light transmitting support through the joining layer under reduced pressure, bubbles and dust contamination are prevented from forming inside the layered body, so that a level surface can be formed and the substrate can maintain the evenness of thickness after grinding.

In still another embodiment of the present disclosure, a method for manufacturing a reduced thickness substrate is provided. The method comprises the steps of preparing the above-described layered body, grinding the substrate to a desired thickness, irradiating the photothermal conversion layer through the light transmitting support to decompose the photothermal conversion layer and thereby to separate the substrate from the light transmitting support after grinding, and peeling the joining layer from the substrate after grinding. In this method, a substrate can be ground to a desired thickness (for example, 150 μm or less, preferably 50 μm or less, more preferably 25 μm or less) on a support. After grinding and additional processes carried out at elevated temperature, the support is separated from the substrate using exposure to radiation energy, so that the joining layer remaining on the substrate after grinding can be easily peeled from the substrate.

### BRIEF DESCRIPTION OF DRAWINGS

FIG. 1 is a cross-sectional view showing a layered body of the present disclosure.

FIGS. 2a and 2b are cross-sectional views showing a vacuum adhesion device useful in the present disclosure.

FIG. 3 is a partial cross-sectional view of a grinding device useful in the method of the present disclosure.

FIGS. 4a, 4a′, 4b, 4c, 4d, and 4e are drawings showing the steps of separating the support and peeling the joining layer.

FIG. 5 is a cross-sectional view of a layered body fixing device which can be used in the laser beam irradiation step.

FIGS. 6a, 6b, 6c, 6d, 6e, and 6f are perspective views of a laser irradiation device.

FIGS. 7a and 7b are schematic views of a pick-up used in the operation of separating wafer and support.

FIG. 8 is a schematic view showing how the joining layer is peeled from the wafer.

### DETAILED DESCRIPTION OF THE DISCLOSURE

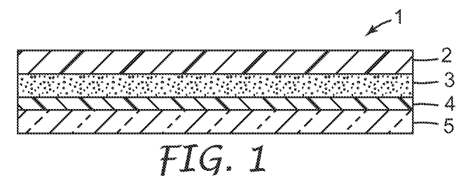

The layered body features a cured acrylate adhesive joining layer for joining the substrate to be ground to a support. In the layered body 1 of FIG. 1, a substrate 2 to be ground, a joining layer 3, a photothermal conversion layer 4 and a support 5 are shown. The elements comprising the layered body of the present disclosure are described in greater detail below.

The joining layer, is used for fixing the substrate to be ground to the support through a photothermal conversion layer. In one embodiment, the joining layer comprises a curable acrylate polymer. In another embodiment, the joining layer comprises a curable acrylate polymer and a curable acrylate adhesion modifying agent. After the separation of the substrate and the support by the decomposition of the photothermal conversion layer, a substrate having the joining layer thereon is obtained. The joining layer may be separated easily from the substrate, such as by peeling. Thus, the joining layer has adhesion strength high enough to fix the substrate to the support yet low enough to permit separation from the substrate even after being exposed to high temperature for extended periods.

In one embodiment of the disclosure, the joining layer can include a curable (meth)acrylate polymer and a curable acrylate adhesion modifying agent. The curable (meth)acrylate polymer can include an (meth)acrylate oligomer, for example, a methacrylated polybutadiene, a polyester (meth)acrylate, a methacrylated isoprene or a polyether (meth)acrylate. The curable acrylate adhesion modifying agent can include for example a silicone acrylate. The adhesive layer can also include a photoinitiator and a reactive diluent. The term “(meth)acrylate” includes acrylate and methacrylate.

Curable acrylate adhesives can provide long-term durability and are useful over a wide range of temperature, humidity and environmental conditions, and can be used effectively to bond the layered body of the disclosure. In some embodiments, the curable adhesives may be photocurable adhesives, including UV and visible light curable adhesives.

Polybutadiene (PBD) can be a non-polar, soft, low modulus polymer having poor adhesion to metals, glass, plastics and other materials. Polybutadiene can be generally unsuited as a coating, primer or adhesion-enhancing additive for rubber and plastic formulations. However, polymers such as polybutadiene having number average molecular weights higher than about 2,000 g/mol can be desirable for use in adhesives and coatings since their relatively high number average molecular weight would result in less shrinkage and more uniform properties upon curing than other materials having lower number average molecular weights, while the polymer backbone would also provide better chemical and moisture resistance, along with elasticity and compatibility with many man-made materials.

The uncured polymeric resin compositions of some embodiments of this disclosure are polymer chains made up of segments having the general formula:

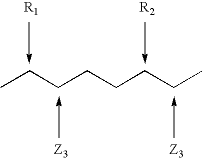

wherein [symbol] denotes a section of the polymeric backbone which can be saturated or unsaturated and may contain one or more members selected from the group consisting of anhydride, amide, ether, ester, aryl and cyclic groups;

wherein the arrows denote that the pendant groups may be attached to the backbone at any point, and that varying quantities of the pendant groups may be present in each of the sections of each molecule of the polymeric resin;

wherein Z can be a hydrocarbyl which does not substantially interfere with crosslinking or stability of the composition, and where a can be 0 or 1 or 2;

wherein R1 can be a group having a combination of chemically bound carboxyl and ester moieties (including ester-like moieties wherein O can be substituted with S, N or P); and

wherein R2 can be a group having a combination of chemically bound carboxyl moieties.

Examples of R1 include:

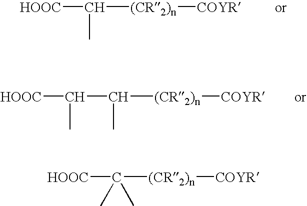

where R′ can be an unsaturation-containing moiety from an acrylic, methacrylic, allylic or vinyl ether compound; and where R″ can be a non-nucleophilic substituent ; where Y can be —O,—N,—S or P ; and where n can be an integer from 0 to 25. For example, n can be an integer from 1 to 5. Also, for example, R″ can be H and n can be 1. Non-nucleophilic substituents include, but are not limited to, H, S, alkyl, aryl, alkoxy, amido, ester, ether, tert-amino, and carboxy.

R′ contains a reactive unsaturation such as acrylate, methacrylate, allyl or vinyl ether, for example, a (meth) acrylate moiety, and also, for example, an alkyl (meth) acrylic ester moiety (for example,—OCH₂CH₂OC (O) C (CH₃)=CH₂).

An example of a R1 group can be:

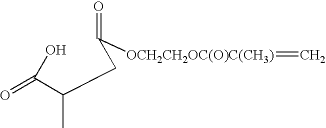

For example, R2 can be:

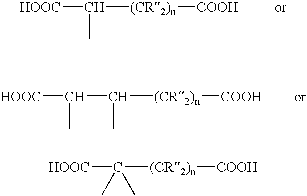

where R″ can be a non-nucleophilic substituent ; where n can be an integer from 0 to 25. For example, n can be an integer from 1 to 5. Also, for example, R″ is H and n can be 1.
An example of a R2 group can be:

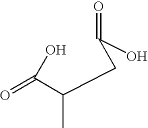

The polymeric backbone, for example, can include a polybutadiene.

A group having a combination of chemically bound carboxyl moieties means that the group has at least 2 carboxyl moieties. A combination of chemically bound carboxyl and ester moieties means that both carboxyl and ester moieties can be present in the same group. Thio-ester, amide or other such hereto-atom containing moieties (including P— containing moieties) may be used in place of ester moieties.

The length of the backbone polymer chains may be selected as desired. For example, the number average molecular weight of the composition can be high enough to ensure low shrinkage at curing along with sufficient flexibility of the cured resins as needed for adhesion properties, but not as high as to limit the ability of polymer molecules to fill the pores and cavities of the substrate surface for an optimal interaction. An exemplary number average molecular weight range can be between about 1,000 and 300,000 g/mol, or for example, between about 2,000 and 100,000 g/mol as determined by gel permeation chromatography (GPC) or any other analytical method.

For example, Z can be H, alkyl, vinyl or alkyl vinyl, providing double bonds which contribute to the crosslinking of the composition; however, Z may be any substituent which can be not so bulky as to interfere with crosslinking and which does not make the composition unstable, i.e., does not provide so many double bonds that crosslinking occurs spontaneously or results in a cured composition more brittle than desired. Adjusting crosslink density by adjusting available sites can be well known to the art and Z may be optimized for compositions of any desired properties by those skilled in the art.

For example, the composition contains a sufficient concentration of acrylate groups with reactive unsaturation to provide fast curing and to add crosslinking density to the cured product for strength and resistance to solvents, chemicals and water, but not so high as to promote spontaneous crosslinking or provide a cured composition that can be more brittle than desired, for example, between about 2 to about 20 acrylate groups or unsaturated moieties are present per backbone polymer chain.

The methods of making some embodiments of this disclosure comprise reacting a polymeric backbone having dicarboxylic acid anhydride and/or pendant carboxyl groups with water and/or one or more unsaturated compounds having a reactive substituent containing a labile hydrogen, such as —OH,—NH, or —SH group or a phosphorous compound to produce a compound having secondary and primary dibasic acid carboxyl functionalities and unsaturated half-ester carboxyl functionalities of different strength. If an anhydride can be used, for example, it can be succinic anhydride.

Primary carboxyl functionality can be that of a dibasic acid having higher acid strength than the other secondary carboxyl functionality of the same acid molecule. Both primary and secondary carboxyl functionalities result from the reaction of dicarboxylic acid anhydride with water. Half-ester carboxyl functionalities of different strength result from the reaction of dicarboxylic acid anhydride groups with one or more unsaturated compounds having a reactive substituent containing labile hydrogen. For example, the unsaturated compound having a reactive substituent containing labile hydrogen can be an acrylate or methacrylate, for example, 2-hydroxyethylmethacrylate. The composition can be made, for example, by reacting a maleic anhydride of polybutadiene with an acrylate-or methacrylate containing compound, water and a half ester of a dibasic acid or a cyclic anhydride that also contains a (meth) acrylate functionality. The amount and type of carboxyl groups present in the compositions may be selected to provide a desired adhesive property to the composition.

Some methacrylated polybutadienes that can be used, for example, include Ricacryl 3100 and Ricacryl 3500, manufactured by Sartomer Company, Exton, Pa., USA. Alternatively, other methacrylated polybutadienes can be used. These include diacrylates of liquid polybutadiene resins composed of modified, esterified liquid polybutadiene diols. These are available under the tradename CN301 and CN303, and CN307, manufactured by Sartomer Company, Exton, Pa., USA. Regardless which methacrylated polybutadiene is used with embodiments of the disclosure, the methacrylated polybutadiene can include a number of methacrylate groups per chain from about 2 to about 20.

In addition, the curable acrylate polymer may include methacrylated isoprene polymers such as Kuraray Liquid Isoprene Rubbers obtained from Kuraray America, Inc. Houston, Tex.

In another embodiment, the curable (meth)acrylate polymer can include a (meth)acrylate oligomer, for example a polyester acrylate. The polyester portion of the polyester acrylate acrylate preferably is the reaction product of a carboxylic diacid and a diol. The carboxylic diacid may be either an alkane dicaboxylic diacids or an aromatic dicarboxylic diacid. Examples of alkane dicarboxylic diacid are adipic acid, decanedicarboxylic acid, and dodecanedicarboxylic acid. Examples of aromatic diacids are ortho-phthalic acid and meta-phthalic acid. The diol may be an alkane diol. Examples of the alkane diol are hexanediol, decandiol, and dodecanediol. The polyester acrylate preferably is a polyester acrylate that is liquid at ambient temperature and that preferably has a weight average molecular weight of less than 20,000 daltons and more preferably less than 5,000 daltons. For example, the curable acrylate polymer may be a polyester acrylate such as CN 294, CN2254, CN 2200 and CN 2280 obtained from Sartomer Company (Exton, Pa.) In addition to the curable acrylate polymer, the joining layer includes a curable acrylate adhesion modifying agent. The joining layer can include a curable acrylate adhesion modifying agent in an amount greater than about 0.1% or an amount less than about 3.0% by weight. The curable acrylate adhesion modifying agent can be silicone polymers substituted with at least one of acrylate group(s) or methacrylate group(s). Preferably the curable acrylate adhesion modifying agent is soluble in the curable acrylate polymer before curing. In addition, it is preferable that the viscosity of the combination of the curable acrylate adhesion modifying agent and the curable acrylate polymer be less than about 10,000 centipoise at ambient temperature and more preferably less than 5,000 centipoise. For example, the curable acrylate adhesion modifying agent may be an acrylate modified silicone polymer, such as Ebecryl 350 from Cytec Industries (West Paterson, N.J.), CN9800 from Sartomer Company (Exton, Pa.) or Tego Rad 2250, Tego Rad 2500, Tego Rad 2650 and Tego Rad 2700 from Evonik Industries (Essen, Germany).

In addition to the curable acrylate polymer and the curable acrylate adhesion modifying agent, the joining layer can also include, for example, photoinitiators. The adhesive joining layer can include a photoinitiator, for example, in an amount between the range of about 0.5% and about 5% by weight. Useful photoinitiators include those known as useful for photocuring free-radically polyfunctional (meth)acrylates. Exemplary photoinitiators include benzoin and its derivatives such as alpha-methylbenzoin; alpha-phenylbenzoin; alpha-allylbenzoin; alpha-benzylbenzoin; benzoin ethers such as benzil dimethyl ketal (e.g., “IRGACURE 651” from Ciba Specialty Chemicals, Tarrytown, N.Y.), benzoin methyl ether, benzoin ethyl ether, benzoin n-butyl ether; acetophenone and its derivatives such as 2-hydroxy-2-methyl-1-phenyl-1-propanone (e.g., “DAROCUR 1173” from Ciba Specialty Chemicals) and 1-hydroxycyclohexyl phenyl ketone (e.g., “IRGACURE 184” from Ciba Specialty Chemicals); 2-methyl-1-[4-(methylthio)phenyl]-2-(4-morpholinyl)-1-propanone (e.g., “IRGACURE 907” from Ciba Specialty Chemicals); 2-benzyl-2-(dimethylamino)-1-[4-(4-morpholinyl)phenyl]-1-butanone (e.g., “IRGACURE 369” from Ciba Specialty Chemicals) and phosphinate derivatives such as Ethyl-2,4,6-trimethylbenzoylphenylphoshinate (e.g. “TPO-L” from BASF, Florham Park, N.J.).

Other useful photoinitiators include, for example, pivaloin ethyl ether, anisoin ethyl ether, anthraquinones (e.g., anthraquinone, 2-ethylanthraquinone, 1-chloroanthraquinone, 1,4-dimethylanthraquinone, 1-methoxyanthraquinone, or benzanthraquinone), halomethyltriazines, benzophenone and its derivatives, iodonium salts and sulfonium salts, titanium complexes such as bis(eta₅-2,4-cyclopentadien-1-yl)-bis[2,6-difluoro-3-(1H-pyrrol-1-yl) phenyl]titanium (e.g., “CGI 784DC” from Ciba Specialty Chemicals); halomethyl-nitrobenzenes (e.g., 4-bromomethylnitrobenzene), mono-and bis-acylphosphines (e.g., “IRGACURE 1700”, “IRGACURE 1800”, “IRGACURE 1850”, and “DAROCUR 4265”. Typically, the initiator is used in amounts ranging from 0.1 to 10%, preferably 2 to 4% by weight.

In addition to the curable acrylate polymer, the curable acrylate adhesion modifying agent and the photoinitiator, the joining layer can also include, for example, reactive diluents. The adhesive joining layer can include, for example, a reactive diluent in an amount between the range of about 10% and about 70% by weight. Reactive diluents can be used to adjust viscosity and/or physical properties of the cured composition. Examples of suitable reactive diluents include mono- and polyfunctional (meth)acrylate monomers (e.g., ethylene glycol di(meth)acrylate, hexanediol, di(meth)acrylate, triethylene glycol di(meth)acrylate, trimethylolpropane tri(meth)acrylate, tripropylene glycol di(meth)acrylate, tetrahydofurfuryl (meth)acrylate, phenoxyethylacrylate.), vinyl ethers (e.g., butyl vinyl ether), vinyl esters (e.g., vinyl acetate), and styrenic monomers (e.g., styrene).

The substrate to be ground, such as a silicon wafer, generally has asperities such as circuit patterns on one side. For the joining layer to fill in the asperities of the substrate to be ground and rendering the thickness of the joining layer uniform, the acrylate adhesive used for the joining layer is preferably in a liquid state during coating and layering and preferably has a viscosity of less than 10,000 centipoise (cps) at the temperature (for example, 25° C.) of the coating and layering operations. This liquid acrylate adhesive is preferably coated by a spin coating method among various methods known in the art. As such an adhesive, a UV-curable or a visible light-curable acrylate adhesive are particularly preferred, because the thickness of the joining layer can be made uniform and moreover, the processing speed is high.

The thickness of the joining layer is not particularly limited as long as it can ensure the thickness uniformity required for the grinding of the substrate to be ground and the tear strength necessary for the peeling of the joining layer from the wafer after removing the support from the layered body, and can sufficiently absorb the asperities on the substrate surface. The thickness of the joining layer is typically from about 10 to about 150 μm, preferably from about 25 to about 100 μm. Prior to assembling the layered body, if desired, the substrate may be partially sawn through on the face adjacent the joining layer (circuit face).

The substrate may be, for example, a brittle material difficult to thin by conventional methods. Examples thereof include semiconductor wafers such as silicon and gallium arsenide, a rock crystal wafer, sapphire and glass.

The light transmitting support is a material capable of transmitting radiation energy, such as a laser beam used in the present disclosure, and the material is required to keep the ground body in a flat state and not cause it to break during grinding and conveyance. The light transmittance of the support is not limited as long as it does not prevent the transmittance of a practical intensity level of radiation energy into the photothermal conversion layer to enable the decomposition of the photothermal conversion layer. However, the transmittance is preferably, for example, 50% or more. Also, in order to prevent the ground body from warping during grinding, the light transmitting support preferably has a sufficiently high stiffness and the flexural rigidity of the support is preferably 2×10⁻³ (Pa·m⁻³) or more, more preferably 3×10⁻² (Pa·m⁻³) or more. Examples of useful supports include glass plates and acrylic plates. Furthermore, in order to enhance the adhesive strength to an adjacent layer such as photothermal conversion layer, the support may be surface-treated with a silane coupling agent or the like, if desired. In the case of using a UV-curable photothermal conversion layer or joining layer, the support preferably transmits ultraviolet radiation.

The support is sometimes exposed to heat generated in the photothermal conversion layer when the photothermal conversion layer is irradiated or when a high temperature is produced due to frictional heating during grinding. Also, for the purpose of forming a metal film on the substrate a process such as vapor deposition or plating may be additionally provided before separating the ground substrate from the support. In addition, a dry etching process may be provided to form vias in the substrate. Particularly, in the case of a silicon wafer, the support is sometimes subjected to a high-temperature process to form an oxide film. Accordingly, a support having heat resistance, chemical resistance and a low expansion coefficient is selected. Examples of support materials having these properties include borosilicate glass available as Pyrex™ and Tenpax™ and alkaline earth boro-aluminosilicate glass such as Corning™#1737 and #7059.

To obtain the desired thickness uniformity after grinding of the substrate, the thickness of the support is preferably uniform. For example, for grinding a silicon wafer to 50 μm or less and attaining evenness of ±10% or less, the variability in the thickness of the support should be reduced to ±2 μm or less. In the case where the support is repeatedly used, the support also preferably has scratch resistance. For repeatedly using the support, the wavelength of the radiation energy and the support may be selected to suppress the damage to the support by the radiation energy. For example, when Pyrex glass is used as the support and a third harmonic generation YAG laser (355 nm) is employed, the separation of the support and the substrate can be performed, however, such a support exhibits low transmittance at the wavelength of this laser and absorbs the radiation energy, as a result, the support is thermally damaged and cannot be reused in some cases.

The photothermal conversion layer contains a light absorbing agent and a heat decomposable resin. Radiation energy applied to the photothermal conversion layer in the form of a laser beam or the like is absorbed by the light absorbing agent and converted into heat energy. The heat energy generated abruptly elevates the temperature of the photothermal conversion layer and the temperature reaches the thermal decomposition temperature of the heat decomposable resin (organic component) in the photothermal conversion layer resulting in decomposition of the resin. The gas generated by the decomposition is believed to form a void layer (such as air space) in the photothermal conversion layer and divide the photothermal conversion layer into two parts, whereby the support and the substrate are separated.

The light-absorbing agent absorbs radiation energy at the wavelength used. The radiation energy is usually a laser beam having a wavelength of 300 to 11,000 nanometers (nm), preferably 300 to 2,000 nm and specific examples thereof include a YAG laser which emits light at a wavelength of 1,064 nm, a second harmonic generation YAG laser at a wavelength of 532 nm, and a semiconductor laser at a wavelength of 780 to 1,300 nm. Although the light absorbing agent varies depending on the wavelength of the laser beam, examples of the light absorbing agent which can be used include carbon black, graphite powder, microparticle metal powders such as iron, aluminum, copper, nickel, cobalt, manganese, chromium, zinc and tellurium, metal oxide powders such as black titanium oxide, and dyes and pigments such as an aromatic diamino-based metal complex, an aliphatic diamine-based metal complex, an aromatic dithiol-base metal complex, a mercaptophenol-based metal complex, a squarylium-based compound, a cyanine-based dye, a methine-based dye, a naphthoquinone-based dye and an anthraquinone-based dye. The light-absorbing agent may be in the form of a film including a vapor deposited metal film. Among these light-absorbing agents, carbon black is particularly useful, because the carbon black significantly decreases the force necessary for separating the substrate from the support after the irradiation and accelerates the separation.

The concentration of the light-absorbing agent in the photothermal conversion layer varies depending on the kind, particle state (structure) and dispersion degree of the light absorbing agent but the concentration is usually from 5 to 70 vol. % in the case of general carbon black having a particle size of approximately from 5 to 500 nm. If the concentration is less than 5 vol. %, heat generation of the photothermal conversion layer may be insufficient for the decomposition of the heat decomposable resin, whereas if it exceeds 70 vol. %, the photothermal conversion layer becomes poor in the film-forming property and may readily cause failure of adhesion to other layers. In the case where the adhesive used as the joining layer is a UV-curable adhesive, if the amount of carbon black is excessively large, the transmittance of the ultraviolet ray through the photothermal conversion layer for curing the adhesive decreases. Therefore, in the case of using a UV-curable acrylate adhesive as the joining layer, the amount of carbon black should be 60 vol. % or less. In order to reduce the force at the time of removing the support after irradiation and thereby prevent abrasion of the photothermal conversion layer during grinding (such as abrasion due to abrasive in wash water), carbon black is preferably contained in the photothermal conversion layer in an amount of 20 to 60 vol. %, more preferably from 35 to 55 vol. %.

Examples of the heat decomposable resin which can be used include gelatin, cellulose, cellulose ester (e.g., cellulose acetate, nitrocellulose), polyphenol, polyvinyl butyral, polyvinyl acetal, polycarbonate, polyurethane, polyester, polyorthoester, polyacetal, polyvinyl alcohol, polyvinylpyrrolidone, a copolymer of vinylidene chloride and acrylonitrile, poly(meth)acrylate, polyvinyl chloride, silicone resin and a block copolymer comprising a polyurethane unit. These resins can be used individually or in combination of two or more thereof. The glass transition temperature (Tg) of the resin is preferably room temperature (20° C.) or more so as to prevent the re-adhesion of the photothermal conversion layer once it is separated due to the formation of a void layer as a result of the thermal decomposition of the heat decomposable resin, and the Tg is more preferably 100° C. or more so as to prevent the re-adhesion. In the case where the light transmitting support is glass, in order to increase the adhesive force between the glass and the photothermal conversion layer, a heat decomposable resin having within the molecule a polar group (e.g., —COOH, —OH) capable of hydrogen-bonding to the silanol group on the glass surface can be used. Furthermore, in applications requiring a chemical solution treatment such as chemical etching, in order to impart chemical resistance to the photothermal conversion layer, a heat decomposable resin having within the molecule a functional group capable of self-crosslinking upon heat treatment, a heat decomposable resin capable of being crosslinked by ultraviolet or visible light, or a precursor thereof (e.g., a mixture of monomers and/or oligomers) may be used. For forming the photothermal conversion layer as an adhesive photothermal conversion layer as shown in FIG. 1, an adhesive polymer formed from poly(meth)acrylate or the like, may be used for the heat decomposable resin.

The photothermal conversion layer may contain a transparent filler, if desired. The transparent filler acts to prevent the re-adhesion of the photothermal conversion layer once it is separated due to the formation of a void layer as a result of the thermal decomposition of the heat decomposable resin. Therefore, the force required for the separation of the substrate and the support, after grinding of the substrate and subsequent irradiation, can be further reduced. Furthermore, since the re-adhesion can be prevented, the latitude in the selection of the heat decomposable resin is broadened. Examples of the transparent filler include silica, talc and barium sulfate. Use of the transparent filler is particularly advantageous when a UV or visible-curable adhesive is used as the joining layer. Further information regarding the use of transparent fillers may be had with reference to Assignee's published application U.S. 2005/0233547 (Noda et al.), incorporated herein by reference, and WO 2005057651.

The photothermal conversion layer may contain other additives, if desired. For example, in the case of forming the layer by coating a heat decomposable resin in the form of a monomer or an oligomer and thereafter polymerizing or curing the resin, the layer may contain a photo-polymerization initiator. Also, the addition of a coupling agent (integral blend method, i.e., the coupling agent is used as an additive in the formulation rather than as a pre-surface-treatment agent) for increasing the adhesive force between the glass and the photothermal conversion layer, and the addition of a crosslinking agent for improving the chemical resistance are effective for their respective purposes. Furthermore, in order to promote the separation by the decomposition of the photothermal conversion layer, a low-temperature gas generator may be contained. Representative examples of the low-temperature gas generator that can be used include a foaming agent and a sublimating agent. Examples of the foaming agent include sodium hydrogencarbonate, ammonium carbonate, ammonium hydrogencarbonate, zinc carbonate, azodicarbonamide, azobisisobutylonitrile, N,N′-dinitrosopentamethylenetetramine, p-toluenesulfonylhydrazine and p,p-oxybis(benzenesulfonylhydrazide). Examples of the sublimating agent include 2-diazo-5,5-dimethylcyclohexane-1,3-dione, camphor, naphthalene, borneol, butyramide, valeramide, 4-tert-butylphenol, furan-2-carboxylic acid, succinic anhydride, 1-adamantanol and 2-adamantanone.

The photothermal conversion layer can be formed by mixing the light absorbing agent such as carbon black, the heat decomposable resin and a solvent to prepare a precursor coating solution, coating this solution on the support, and drying it. Also, the photothermal conversion layer can be formed by mixing the light absorbing agent, a monomer or an oligomer as a precursor material for the heat decomposable resin and, optionally, additives such as photo-polymerization initiator, and a solvent, if desired, to prepare a precursor coating solution in place of the heat decomposable resin solution, coating the solution on the support, drying and polymerizing/curing it. For the coating, a general coating method suitable for coating on a hard support, such as spin coating, die coating, and roll coating, can be used.

In general, the thickness of the photothermal conversion layer is not limited as long as it permits the separation of the support and the substrate, but it is usually 0.1 μm or more. If the thickness is less than 0.1 μm, the concentration of the light-absorbing agent required for sufficient light absorption becomes high and this deteriorates the film-forming property, and as a result, adhesion to the adjacent layer may fail. On the other hand, if the thickness of the photothermal conversion layer is 5 μm or more while keeping constant the concentration of the light-absorbing agent required to permit the separation by the thermal decomposition of the photothermal conversion layer, the light transmittance of the photothermal conversion layer (or a precursor thereof) becomes low. As a result, when a photo-curable, for example, an ultraviolet (UV)-curable photothermal conversion layer, and a joining layer are used, the curing process is sometimes inhibited to the extent that a sufficiently cured product cannot be obtained. Therefore, in the case where the photothermal conversion layer is, for example, ultraviolet-curable, in order to minimize the force required to separate the substrate from the support after irradiation and to prevent the abrasion of the photothermal conversion layer during grinding, the thickness of the photothermal conversion layer is preferably from about 0.3 to about 3 μm, more preferably from about 0.5 to about 2.0 μm.

Since the substrate to be ground of the layered body of the present disclosure can be a wafer having formed thereon a circuit, the wafer circuit may be damaged by radiation energy such as a laser beam reaching the wafer through the light transmitting support, the photothermal conversion layer and the joining layer. To avoid such circuit damage, a light absorbing dye capable of absorbing light at the wavelength of the radiation energy or a light reflecting pigment capable of reflecting the light may be contained in any of the layers constituting the layered body or may be contained in a layer separately provided between the photothermal conversion layer and the wafer. Examples of light absorbing dyes include dyes having an absorption peak in the vicinity of the wavelength of the laser beam used (for example, phthalocyanine-based dyes and cyanine-based dyes). Examples of light reflecting pigments include inorganic white pigments such as titanium oxide.

The layered body of the present disclosure may comprise additional layers other than the substrate to be ground, the joining layer in contact with the substrate to be ground, the photothermal conversion layer and the light transmitting support. Examples of the additional layer include a first intermediate layer (not shown) between the joining layer 3 and the photothermal conversion layer 4, and/or a second intermediate layer (not shown) provided between the photothermal conversion layer 4 and the support 5. The second intermediate layer is preferably joined to the support 5 through a joining layer 3.

In the case where the first intermediate layer is provided, the layered body 1 is separated at the photothermal conversion layer 4 after the irradiation and a layered body of first intermediate layer/joining layer 3/substrate 2 is obtained. Therefore, the first intermediate layer acts as a backing during the separation of the joining layer 3 from substrate 2 and enables the easy separation of the two. The first intermediate layer is preferably a multilayer optical film. Also, the first intermediate layer is preferably a film which selectively reflects the radiation energy used to enable the separation, such as YAG laser (near infrared wavelength light). This film is preferred because when the first intermediate layer does not transmit but reflects radiation energy, the radiation energy is prevented from reaching the wafer surface, where circuitry is present, and this eliminates the possibility of damage to the circuitry.

In the case of using a photocurable acrylate adhesive as the joining layer 3, a film having a sufficiently high transmittance for curing light such as ultraviolet light is preferred. Accordingly, the multilayer optical film is preferably transmissive to ultraviolet light and selectively reflects near infrared light. The preferred multilayer optical film which is transmissive to ultraviolet light and reflects near infrared light is available as 3M™ Solar Reflecting Film (3M Company, St. Paul, Minn.). The first intermediate layer functions as a substrate for the removal of joining layer 3 from substrate 2 by peeling and therefore, preferably has a thickness of 20 μm or more, more preferably 30 μm or more, and a breaking strength of 20 MPa or more, more preferably 30 MPa or more, still more preferably 50 MPa or more.

In the case where the above-described second intermediate layer is provided, a layered body of second intermediate layer/joining layer 3/light transmitting support 5 is obtained after the irradiation of the layered body 1. Therefore, the second intermediate layer acts as a backing during the separation of the joining layer 3 and support 5 and enables the easy separation of the two. As such, by providing a second intermediate layer, the photothermal conversion layer 4 or the joining layer 3 (curable acrylate adhesive) is prevented from remaining on the light transmitting support 5, and the support 5 can be easily recycled. In order to enable the removal of joining layer 3 from support 5 by peeling them apart after the laser irradiation and without rupturing, the second intermediate layer preferably has a thickness of 20 μm or more, more preferably 30 μm or more, and a breaking strength of 20 MPa or more, more preferably 30 MPa or more, still more preferably 50 MPa or more. In some cases, the resin of the second intermediate layer permeates into the photothermal conversion layer 4, such as when the second intermediate layer is coated as a mixture of photocurable oligomer and monomer and cured with UV (e.g., when the sheet is produced by coating photothermal conversion layer on the film substrate, coating the second intermediate layer on photothermal conversion layer and curing it, and coating the joining layer on the second intermediate layer). In such cases, in order to prevent re-adhering of the surface separated with a space formed by the laser irradiation, the T_{g} of the resin of the second intermediate layer (in the case of a photocurable resin, the T_{g} of the cured resin) may be 40° C. or more.

In the manufacture of the layered body, it is important to prevent undesirable foreign substances such as air from entering between layers. For example, if air enters between layers, the thickness uniformity of the layered body is prevented and the substrate to be ground cannot be ground to a thin substrate. In the case of manufacturing a layered body 1 shown in FIG. 1, the following method, for example, may be considered. First, the precursor coating solution of the photothermal conversion layer 4 is coated on the support 5 by any one of the methods known in the art, dried and cured by irradiating with ultraviolet light or the like. Thereafter, the curable acrylate adhesive is coated on either one or both of the surface of the cured photothermal conversion layer 4 and the surface of the substrate 2 on the non-ground side. The photothermal conversion layer 4 and the substrate 2 are attached through the curable acrylate adhesive, which is then cured to form the joining layer 3, for example, by irradiating with ultraviolet light from the support side, whereby a layered body can be formed. The formation of such a layered body is preferably performed under vacuum to prevent air from entering between layers. This can be attained by, for example, by modifying a vacuum adhesion device such as that described in Japanese Unexamined Patent Publication (Kokai) No. 11-283279.

The layered body is preferably designed such that it is free from the invasion of water used during grinding of the substrate, has an adhesive strength between layers so as not to cause dropping off of the substrate, and has an abrasion resistance so as to prevent the photothermal conversion layer from being abraded by the water flow (slurry) containing dusts of the ground substrate.

A thinned substrate can be manufactured by the method comprising preparing a layered body formed as above, grinding the substrate, to a desired thickness, applying radiation energy to the photothermal conversion layer through the light transmitting support to decompose the photothermal conversion layer and thereby to separate the ground substrate from the light transmitting support, and peeling the joining layer from the substrate.

In one aspect, the method of the present disclosure is described below by referring to the drawings. In the following, a laser beam is used as the radiation energy source and a silicon wafer is used as the substrate to be ground, however, the present disclosure is not limited thereto.

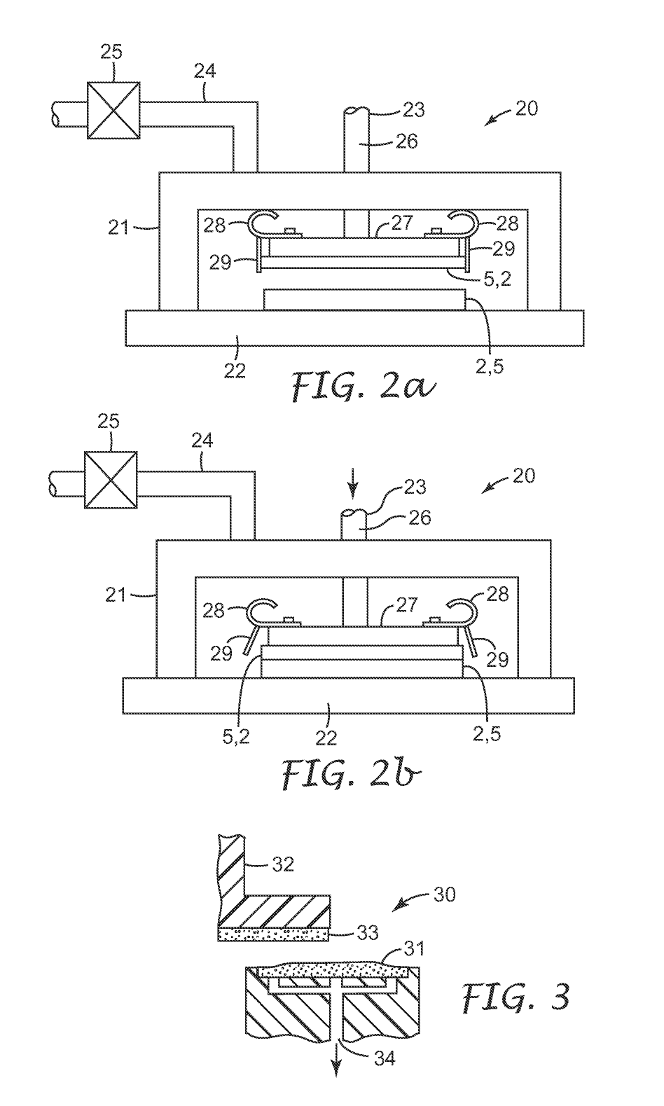

FIG. 2 shows a cross-sectional view of a vacuum adhesion device suitable for the production of the layered body of one embodiment of the present disclosure. A vacuum adhesion device 20 comprises a vacuum chamber 21; a supporting part 22 provided in the vacuum chamber 21, on which either one of a substrate 2 to be ground (silicon wafer) or a support 5 is disposed; and holding/releasing means 23 provided in the vacuum chamber 21 and movable in the vertical direction at the upper portion of the supporting part 22, which holds the other one of the support 5 or the silicon wafer 2. The vacuum chamber 21 is connected to a pressure reducing device 25 via pipe 24, so that the pressure inside the vacuum chamber 21 can be reduced. The holding/releasing means 23 has a shaft 26 movable up and down in the vertical direction, a contact surface part 27 provided at the distal end of the shaft 26, leaf springs 28 provided in the periphery of the contact surface part 27, and holding claws 29 extending from each leaf spring 28. As shown in FIG. 2(a), when the leaf springs are in contact with the upper surface of the vacuum chamber 21, the leaf springs are compressed and the holding claws 29 are directed toward the vertical direction to hold the support 5 or the wafer 2 at peripheral edges. On the other hand, as shown in FIG. 2(b), when the shaft 26 is pressed down and the support 5 or the wafer 2 is in close proximity to the wafer 2 or the support 5 respectively disposed on the supporting part, the holding claws 29 are released together with the leaf springs 28 to superimpose the support 5 and the wafer 2.

Using this vacuum adhesion device 20, the layered body can be manufactured as follows. First, as described above, a photothermal conversion layer is provided on a support 5. Separately, a wafer to be layered is prepared. On either one or both of the wafer 2 and the photothermal conversion layer of the support 5, an adhesive for forming a joining layer is applied. The thus-prepared support 5 and wafer 2 are disposed in the vacuum chamber 21 of the vacuum adhesion device 20 as shown in FIG. 2(a), the pressure is reduced by the pressure reducing device, the shaft 26 is pressed down to layer or laminate the wafer as shown in FIG. 2(b) and after opening to air, the adhesive is cured, if desired, to obtain a layered body.

FIG. 3 shows a partial cross-sectional view of a grinding device useful in an embodiment of the disclosure. The grinding device 30 comprises a pedestal 31 and a grinding wheel 33 rotatably mounted on the bottom end of a spindle 32. A suction port 34 is provided adjacent the pedestal 31 and the suction port 34 is connected to a pressure reducing device (not shown), whereby a material to be ground is suctioned and fixed on the pedestal 31 of the grinding device 30. The layered body 1 of the present disclosure as shown in FIG. 1 is prepared and used as a material to be ground. The support side of the layered body 1 is mounted on the pedestal 31 of the grinding device 30 and fixed by suction using a pressure-reducing device. Thereafter, while feeding a fluid flow (such as water or any solution known useful in wafer grinding), the grinding wheel 33 under rotation is brought into contact with the layered body 1, thereby performing the grinding. The grinding can be performed to a thin level of 150 μm or less, preferably 50 μm or less, more preferably 25 μm or less.

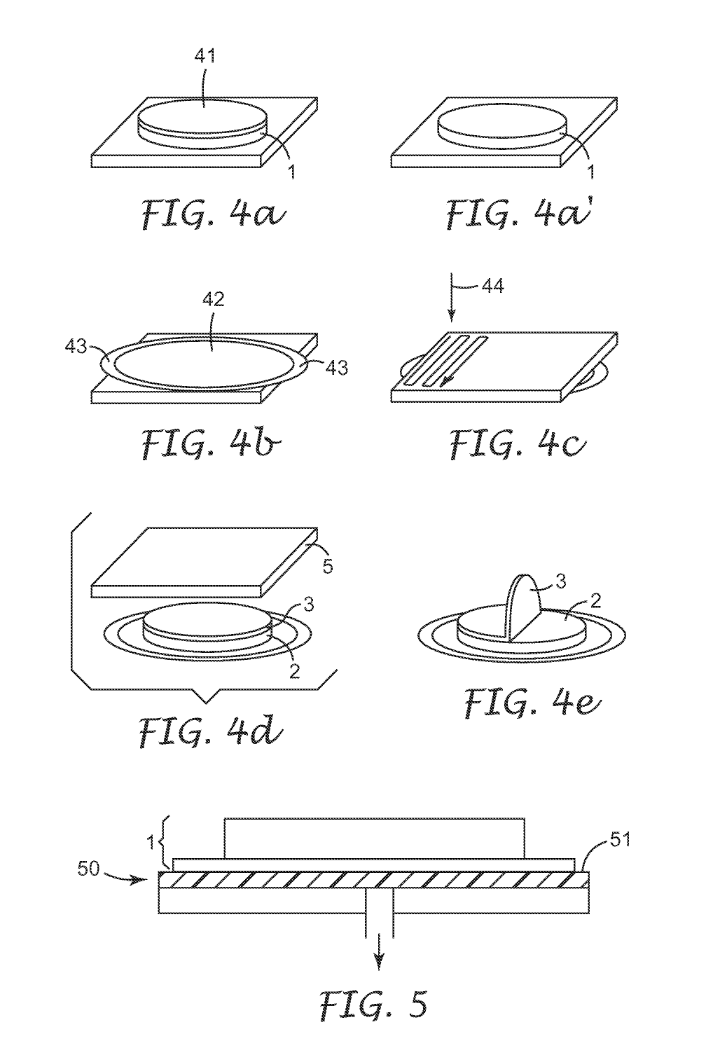

After grinding to the desired level, the layered body 1 is removed and conveyed to subsequent steps, where the separation of the wafer and the support by irradiation with a laser beam and the peeling of the joining layer from the wafer are performed. FIG. 4 shows a drawing of the steps of separating the support and peeling of the joining layer. First, by taking account of the final step of dicing, a die bonding tape 41 is disposed, if desired, on the ground surface of the wafer side of the layered body 1 (FIG. 4(a)) or the die bonding tape 41 is not disposed (FIG. 4(a′)), and thereafter, a dicing tape 42 and a dicing frame 43 are disposed (FIG. 4(b)). Subsequently, a laser beam 44 is irradiated from the support side of the layered body 1 (FIG. 4(c)). After the irradiation of the laser beam, the support 5 is picked up to separate the support 5 from the wafer 2 (FIG. 4(d)). Finally, the joining layer 3 is separated by peeling to obtain a thinned silicon wafer 2 (FIG. 4(e)).

Usually, a semiconductor wafer such as silicon wafer is subjected to chamfering called beveling so as to prevent edges from damage due to impact. That is, the comers at edge parts of a silicon wafer are rounded. When a liquid adhesive is used as the joining layer and coated by spin coating, the joining layer is spread to the edge parts and the adhesive is exposed to edge parts of the grinding surface. As a result, in disposing a dicing tape, not only the ground wafer but also the exposed adhesive come into contact with the pressure-sensitive adhesive of the dicing tape. When the adhesion of the dicing tape used is strong, the joining layer is sometimes difficult to separate. In such a case, it is preferred to previously remove a part of the exposed adhesive before disposing a dicing tape and a dicing frame. For the removal of the exposed adhesive at edge parts, radiation energy or a CO₂ laser (wavelength of 10.6 μm) can be used which the adhesive can sufficiently absorb.

FIG. 5 shows a cross-sectional view of a layered body fixing device which can be used, for example, in the step of irradiating, such as with a laser beam in one aspect of the disclosure. The layered body 1 is mounted on a fixing plate 51 such that the support comes as the upper surface with respect to the fixing device 50. The fixing plate 51 is made of a porous metal such as sintered metal or a metal having surface roughness. The pressure is reduced from the lower part of the fixing plate 51 by a vacuum device (not shown), whereby the layered body 1 is fixed by suction onto the fixing plate 51. The vacuum suction force is preferably strong enough not to cause dropping in the subsequent steps of separating the support and peeling of the joining layer. A laser beam is used to irradiate the layered body fixed in this manner. For emitting the laser beam, a laser beam source having an output high enough to cause decomposition of the heat decomposable resin in the photothermal conversion layer at the wavelength of light absorbed by the photothermal conversion layer is selected, so that a decomposition gas can be generated and the support and the wafer can be separated. For example, a YAG laser (wavelength of 1,064 nm), a second harmonic YAG laser (wavelength: 532 nm) and a semiconductor laser (wavelength: from 780 to 1,300 nm) can be used.

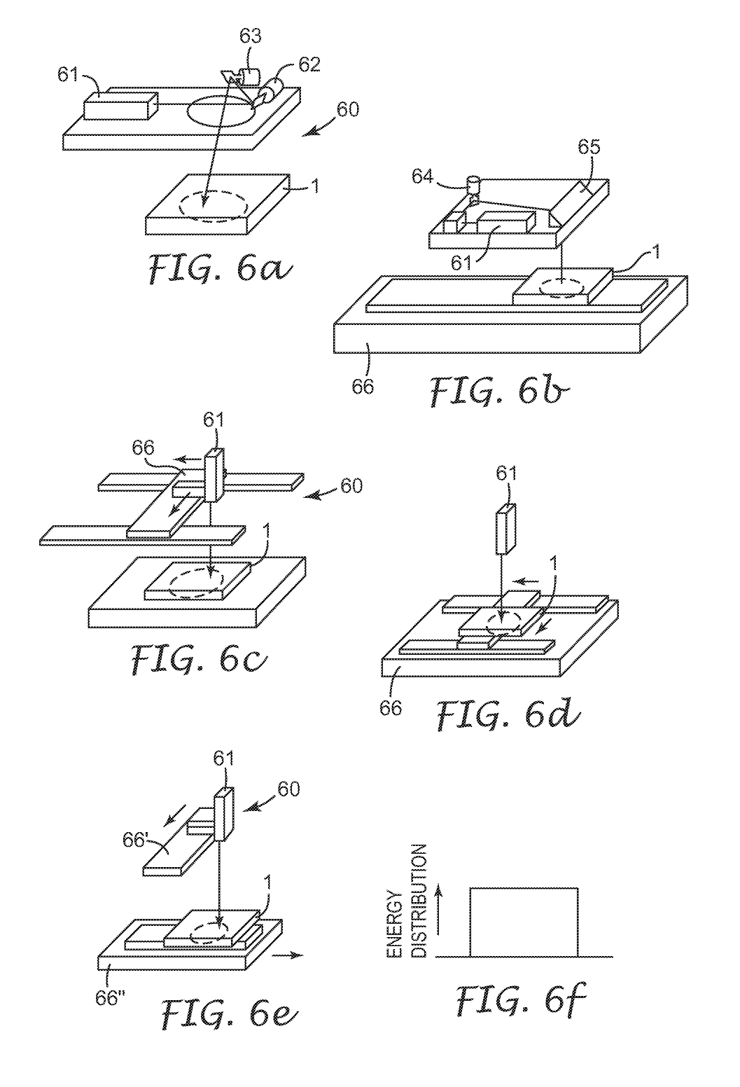

As the laser irradiation device, a device capable of scanning a laser beam to form a desired pattern on the irradiated surface and capable of setting the laser output and the beam moving speed is selected. Also, in order to stabilize the processing quality of the irradiated material (layered body), a device having a large focus depth is selected. The focus depth varies depending on the dimensional precision in the design of device and is not particularly limited but the focus depth is preferably 30 μm or more. FIG. 6 shows a perspective view of a laser irradiation device which can be used in the present disclosure. The laser irradiation device 60 of FIG. 6(a) is equipped with a galvanometer having a biaxial configuration composed of the X axis and the Y axis and is designed such that a laser beam oscillated from a laser oscillator 61 is reflected by the Y axis galvanometer 62, further reflected by the X axis galvanometer 63 and irradiated on the layered body 1 on the fixing plate. The irradiation position is determined by the directions of the galvanometers 62 and 63. The laser irradiation device 60 of FIG. 6(b) is equipped with a uniaxial galvanometer or a polygon mirror 64 and a stage 66 movable in the direction orthogonal to the scanning direction. A laser beam from the laser oscillator 61 is reflected by the galvanometer or polygon 64, further reflected by a hold mirror 65 and irradiated on the layered body 1 on the movable stage 66. The irradiation position is determined by the direction of the galvanometer or polygon 64 and the position of the movable stage 66. In the device of FIG. 6(c), a laser oscillator 61 is mounted on a movable stage 66 which moves in the biaxial direction of X and Y, and a laser is irradiated on the entire surface of the layered body 1. The device of FIG. 6(d) comprises a fixed laser oscillator 61 and a movable stage 66 which moves in the biaxial direction of X and Y. The device of FIG. 6(e) has a constitution such that a laser oscillator 61 is mounted on a movable stage 66′ which can move in the uniaxial direction and a layered body 1 is mounted on a movable stage 66″ which can move in the direction orthogonal to the movable stage 66′.

When there is concern about damaging the wafer of the layered body 1 by the laser irradiation, a top hat beam form (see FIG. 6(f)) having a steep energy distribution and very reduced leakage energy to the adjacent region is preferably formed. The beam form may be changed by any known method, for example, by (a) a method of deflecting the beam by an acousto-optic device, a method of forming a beam using refraction/diffraction, or (b) a method of cutting the broadening portion at both edges by using an aperture or a slit.

The laser irradiation energy is determined by the laser power, the beam scanning speed and the beam diameter. For example, the laser power that can be used is, but not limited to, from 0.3 to 100 watts (W), the scanning speed is from 0.1 to 40 meters/second (m/s), and the beam diameter is from 5 to 300 μm or more. In order to increase the speed of this step, the laser power is enhanced and thereby the scanning speed is increased. Since the number of scans can be further reduced as the beam diameter becomes larger, the beam diameter may be increased when the laser power is sufficiently high.

The heat decomposable resin in the photothermal conversion layer is decomposed by the laser irradiation to generate a gas that creates cracks inside the layer to separate the photothermal conversion layer itself. If air enters in between the cracks, re-adhesion of the cracks can be prevented. Therefore, in order to facilitate the entering of air, it is desirable to perform the beam scanning from the edge part of the layered body to the interior of the layered body.

As described above, the glass transition temperature (T_{g}) of the photothermal conversion layer is preferably room temperature (20° C.) or more. This is because the separated cracks may re-adhere to one another during the cooling of the decomposed resin and make the separation impossible. The re-adhesion is considered to occur due to the fact that the cracks of the photothermal conversion layer become attached with each other under the weight of the support. Therefore, the re-adhesion can be prevented when the irradiation process is contrived not to impose the weight of the support, for example, by performing the laser irradiation in the vertical direction from the lower part to the upper part (namely, by performing the laser irradiation in a configuration such that the support comes to the bottom side) or by inserting a hook between the wafer and the photothermal conversion layer from the edge part and lifting the layer.

To employ a laser beam from the edge part of the layered body, a method of applying the laser beam while linearly reciprocating it from the edge part to the tangential direction of wafer or, alternatively, a method of spirally irradiating the laser beam from the edge part to the center like a phonograph record may be used.

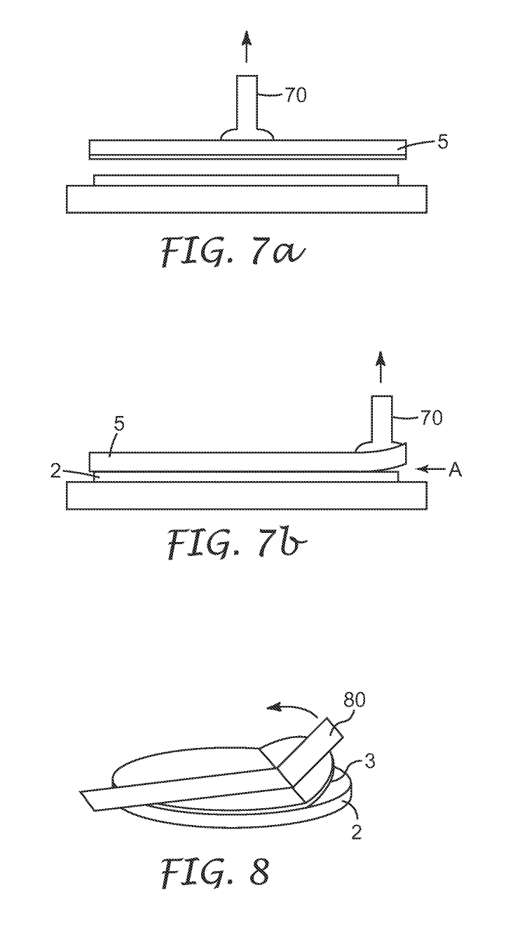

After the laser irradiation, the support is separated from the wafer and for this operation a general pick-up using a vacuum is used. The pick-up is a cylindrical member connected to a vacuum device having a suction device at the distal end. FIG. 7 shows a schematic view of a pick-up for use in the separation operation of the wafer and the support. In the case of FIG. 7(a), the pick-up 70 is generally in the center of the support 5 and picked up in a generally vertical direction, thereby peeling off the support. Also, as shown in FIG. 7(b), the pick-up 70 is at the edge part of the support 5 and by peeling while blowing a compressed air (A) from the side to enter air between the wafer 2 and the support 5, the support can be more easily peeled off.

After removing the support, the joining layer on the wafer is removed. FIG. 8 is a schematic view showing how the joining layer is peeled. For the removal of the joining layer 3, preferably, an adhesive tape 80 for removing the joining layer, which can create a stronger adhesive bond with joining layer 3 than the adhesive bond between the wafer 2 and the joining layer 3, can be used. Such an adhesive tape 80 is placed to adhere onto the joining layer 3 and then peeled in the arrow direction, whereby the joining layer 3 is removed.

Finally, a thinned wafer remains in the state of being fixed to a dicing tape or a die frame with or without a die bonding tape. This wafer is diced in a usual manner, thereby completing a chip. However, the dicing may be performed before the laser irradiation. In such a case, it is also possible to perform the dicing step while leaving the wafer attached to the support, then subject only the diced region to the laser irradiation and separate the support only in the diced portion. The present disclosure may also be applied separately to a dicing step without using a dicing tape, by re-transferring through a joining layer the ground wafer onto a light transmitting support having provided thereon a photothermal conversion layer.

The methods disclosed herein allow the layered body to be subjected to higher temperature processes than prior art methods. In the manufacture of semiconductor wafers, the instant method allows subsequent processing steps. One such exemplary processing step can be sputtering techniques such as, for example, metal deposition processing for electrical contacts. Another such exemplary processing step can be dry etching techniques such as, for example, reactive ion etching for creating vias in the substrate. Another such exemplary processing step can be thermocompression bonding such as, for example, bonding an additional layer to the wafer. Embodiments of the disclosure are advantageous because the layered body can be subjected to these processing steps while still allowing the joining layer to be easily removed from the ground substrate (wafer). In some embodiments the layered body comprising a cured methacrylated polybutadiene adhesive joining layer may be subjected to temperatures in excess of 150° C. In some embodiments the layered body comprising a cured methacrylated polybutadiene adhesive joining layer can be subjected to temperatures of 200° C. and even 250° C. Embodiments of this disclosure provide that the adhesive can be heated to at least 250 degrees Celsius for at least one hour and still maintain its mechanical integrity and adhesion while also able to be cleanly removed from a substrate.

The present disclosure is effective, for example, in the following applications.

### 1. Layered CSP (Chip Scale Package) for High-Density Packaging

The present disclosure is useful, for example, with a device form called system-in-package where a plurality of Large Scale Integrated (LSI) devices and passive parts are housed in a single package to realize multifunction or high performance, and is called a stacked multi-chip package. According to the present disclosure, a wafer of 25 μm or less can be reliably manufactured in a high yield for these devices.

### 2. Through-Type CSP Requiring High Function and High-Speed Processing

In this device, the chips are connected by a through electrode, whereby the wiring length is shortened and the electrical properties are improved. To solve technical problems, such as formation of a through hole for forming a through electrode and embedding of copper in the through hole, the chip may be further reduced in the thickness. In the case of sequentially forming chips having such a configuration by using the layered body of the present disclosure, an insulating film and a bump (electrode) may be formed on the back surface of the wafer and the layered body needs resistance against heat and chemicals. Even in this case, when the above-described support, photothermal conversion layer and joining layer are selected, the present disclosure can be effectively applied.

3. Thin Compound Semiconductor (e.g. GaAs) Improved in Heat Radiation Efficiency, Electrical Properties and Stability

Compound semiconductors such as gallium arsenide are being used for high-performance discrete chips, laser diode and the like because of their advantageous electrical properties (high electron mobility, direct transition-type band structure) over silicon. Using the layered body of the present disclosure and thereby reducing the thickness of the chip increases the heat dissipation efficiency thereof and improves performance. At present, the grinding operation for thickness reduction and the formation of an electrode are performed by joining a semiconductor wafer to a glass substrate as the support using a grease or a resist material. Therefore, the joining material may be dissolved by a solvent for separating the wafer from the glass substrate after the completion of processing. This is accompanied with problems that the separation requires more than several days time and the waste solution should be treated. These problems can be solved when the layered body of the present disclosure is used.

### 4. Application to Large Wafer for Improving Productivity

In the case of a large wafer (for example, a 12 inch-diameter silicon wafer), it is very important to separate the wafer and the support easily. The separation can be easily performed when the layered body of the present disclosure is used, and therefore, the present disclosure can be applied also to this field.

### 5. Thin Rock Crystal Wafer

In the field of rock crystal wafer, the thickness reduction of a wafer is required to increase the oscillation frequency. The separation can be easily performed when the layered body of the present disclosure is used, and therefore, the present disclosure can be applied also to this field.

### 6. Thin Glass for Liquid Crystal Display

In the field of liquid crystal display, the thickness reduction of the glass is desired to reduce the weight of the display and it is desired that the glass be uniform thickness. The separation can be easily performed when the layered body of the present disclosure is used, and therefore, the present disclosure can be applied also to this field.

### EXAMPLES

These examples are for illustrative purposes only and are not meant to be limiting on the scope of the claims. All parts, percentages, ratios, etc. in the examples and the rest of the specification are by weight, unless noted otherwise.

Table 1 shows the formulation components and trade names that were used in the following examples. The following formulation components do not constitute an exclusive list, but should be interpreted only in light of the comparative examples for which they were used. Those skilled in the art will understand other formulation components may also correspond to a reasonable interpretation of the claims.

### Heat Aged Adhesion Testing

Samples for adhesion testing are prepared by coating an approximately 250 micrometer thick layer of the adhesive formulation between a silicon wafer and a polyester release liner using a standard notch bar coater. The adhesive coating was passed three times under a Fusion “D” bulb set on low power. The conveyer speed was 30 feet per minute. The release liner was removed from the irradiated sample, and the sample was placed on a nitrogen inerted hot plate set at the designated temperature (model CE 1100 available from Cost Effective Equipment Co.). The sample was heated for one hour, removed from the hot plate and allowed to cool to ambient temperature. Tape (3M #3305) was laminated to the heat aged adhesive sample, the sample was trimmed to a 25 mm width, and the force to peel the adhesive from the wafer at a 90 degree angle was measured. The peel rate was 125 mm/minute.

TABLE 1
Formulation components

| Component | Supplier | Description |
|---|---|---|
| LC-4000 | 3M | Prototype WSS High Temperature |
| | St Paul, MN | Adhesive |
| Ricacryl 3500 | Sartomer Company | Highly functional methacrylated |
| | Exton, PA | polybutadiene |
| SR 238 | Sartomer | 1,6 Hexanediol diacrylate |
| Bisomer | Cognis | Polypropylene glycol (400) |
| PPG400DMA | Cincinnati, OH | diacrylate |
| Irgacure 369 | Ciba Corporation | UV photoinitiator |
| | Tarrytown, NY | |
| Ebecryl 350 | Cytec Industries | Silicone diacrylate |
| | West Paterson, NJ | |
| CN2280 | Sartomer | Polyester acrylate oligomer |
| CN294E | Sartomer | Tetrafunctional acrylated polyester |
| | | oligomer. |
| SR339 | Sartomer | 2-Phenoxyethyl acrylate |
| Elvacite 4059 | Lucite International | Reactive polymeric toughener |
| | Cordova, TN | |
| Lucirin^{R} | BASF | UV-photoinitiator |
| TPO-L | Florham Park, NJ | |

### Adhesive Sample Preparation

For adhesive samples that included components of high viscosity, those components were heated for one hour in an oven set at 60 degrees Celsius. The lower viscosity components were added to the heated component and the mixture was blended for one hour on a stir plate. Samples that included components of sufficiently low viscosity were blended at ambient temperature. A photoinitiator was added to an oligomer or oligomer/diluent combination and the total mixture was blended for one hour. The total mixture was treated in a vacuum dessicator for from 10 minutes to one hour.

TABLE 2
Formulation Examples (composition in parts)

| | Ricacryl | | Bisomer | | | Ebecryl | Irgacure | |
|---|---|---|---|---|---|---|---|---|
| Example # | 3500 | SR238 | PPG400DMA | SR 285 | SR339 | 350 | 369 | TPO-L |
| Example 1 | 60 | 37 | 0 | 0 | 0 | 1 | 2 | 0 |
| Comparative | 61.9 | 36.1 | 0 | 0 | 0 | 0 | 2 | 0 |
| Example A | | | | | | | | |
| Example 2 | 55.6 | 10.7 | 0 | 5.9 | 25.4 | 0.5 | 0 | 2.0 |
| Comparative | 55.9 | 10.8 | 0 | 5.9 | 25.5 | 0 | 0 | 2.0 |
| Example B | | | | | | | | |
| Comparative | 62 | 0 | 36 | 0 | 0 | 0 | 2 | 0 |
| Example C | | | | | | | | |

TABLE 3
Formulation Examples (Composition in parts)

| | | | | Elvacite | Ebecryl | |
|---|---|---|---|---|---|---|
| | CN2280 | CN294E | SR339 | 4059 | 350 | TPO-L |
| Example 3 | 29 | 29 | 32 | 6 | 2 | 2 |
| Comparative | 29 | 29 | 32 | 6 | None | 2 |
| Example D | | | | | | |

TABLE 4
Test Results

| | Peel Force after Heat Aging |
|---|---|
| | at 250 C. for one hour |
| Example # | (N/25 mm) |
| Example 1 | 1.0 |
| Comparative Example A | 1.5 |
| Example 2 | <0.1 |
| Comparative Example B | 3.0 |
| Comparative Example C | No release |
| Example 3 | 2.0 |
| Comparative Example D | No Release |

As the data in Table 4 shows, the peel force after heat aging of Comparative Example A is higher than Example 1. Similarly, the peel force for Comparative Example B is substantially higher than Example 2. Both Examples 1 and 2 contained the curable acrylate modifying agent. Comparative Example C, which did not include the modifying agent, did not release after heat aging. Finally Example 3 was able to release after heat aging while Comparative Example D did not release.

What is claimed is:

1. A method for manufacturing a layered body,
the layered body comprising:
a substrate to be ground;
a joining layer in contact with said substrate;
a photothermal conversion layer comprising a light absorbing agent and
a heat decomposable resin disposed adjacent the joining layer; and
a light transmitting support disposed adjacent the photothermal conversion layer,
the method comprising the steps of:
coating on the light transmitting support a photothermal conversion layer precursor containing a light absorbing agent and a heat decomposable resin solution or a monomer or oligomer as a precursor material of the heat decomposable resin;
drying to solidify or cure the photothermal conversion layer precursor to form a photothermal conversion layer on the light transmitting support;
applying the joining layer comprising a curable acrylate polymer and a curable acrylate adhesion modifying agent to the substrate to be ground or to the photothermal conversion layer; and
joining the substrate to be ground and the photothermal conversion layer through the joining layer under reduced pressure, and curing to form the layered body.

2. The method of claim 1, wherein the joining layer comprises an adhesive having a number average molecular weight between about 1,000 and 300,000 g/mol.

3. The method of claim 1, wherein the joining layer further comprises a reactive diluent in an amount between about 10% and about 70% by weight.

4. The method of claim 1, wherein the joining layer further comprises a photoinitiator in an amount between about 0.5% and 5% by weight.

5. The method of claim 1 wherein the curable acrylate adhesion modifying agent is a silicone polymer substituted with (meth)acrylate groups.

6. A method for modifying a semiconductor wafer comprising the steps of:
applying a photothermal conversion layer comprising a light-absorbing agent and a heat decomposable resin on a light-transmitting support, preparing a semiconductor wafer having a circuit face with a circuit pattern and a non-circuit face on the side opposite of the circuit face, layering the semiconductor wafer and the light-transmitting support through a joining layer including a curable acrylate polymer and a curable acrylate adhesion modifying agent by placing the circuit face and said photothermal conversion layer to face each other, and irradiating light through the light-transmitting support to cure the joining layer, thereby forming a layered body having a non-circuit face on the outside surface,
grinding the non-circuit face of the semiconductor wafer until the semiconductor wafer reaches a desired thickness,
exposing the photothermal conversion layer to radiation through the light-transmitting support to decompose the photothermal conversion layer, and separating the wafer with said joining layer from the light-transmitting support; and
removing the joining layer from the semiconductor wafer.

7. The method of claim 6, wherein the joining layer comprises an adhesive having a number average molecular weight between about 1,000 and 300,000 g/mol.

8. The method of claim 6, wherein the joining layer further comprises a reactive diluent in an amount between about 10% and about 70% by weight.

9. The method of claim 6, wherein the joining layer further comprises a photoinitiator in an amount between about 0.5% and about 5% by weight.

10. The method of claim 6, further comprising affixing a die bonding tape to the semiconductor wafer, and optionally dicing the ground semiconductor wafer.

11. The method of claim 6, wherein adhering the semiconductor wafer and the light-transmitting support through the joining layer is performed in a vacuum.

12. The method of claim 6, wherein the curable acrylate adhesion modifying agent includes a silicone polymer substituted with (meth)acrylate groups.

13. A layered body comprising:
a substrate to be ground;
a curable joining layer including a curable acrylate polymer and a curable acrylate adhesion modifying agent in contact with the substrate;
a photothermal conversion layer comprising a light absorbing agent and a heat decomposable resin disposed adjacent the joining layer; and
a light transmitting support disposed adjacent the photothermal conversion layer.

14. A method of providing a thin substrate comprising:
providing a layered body comprising (i) a substrate to be ground; (ii) a joining layer including a curable acrylate polymer and a curable acrylate adhesion modifying agent in contact with the substrate; (iii) a photothermal conversion layer comprising a light absorbing agent and a heat decomposable resin disposed adjacent the joining layer; and (iv) a light transmitting support disposed adjacent the photothermal conversion layer;
grinding a face of said substrate to a desired thickness; and
irradiating radiation energy through the light-transmitting support side to decompose said photothermal conversion layer, thereby causing separation into a thin substrate having the joining layer and a light-transmitting support, and optionally removing said cured joining layer from said ground substrate.

15. The method of claim 14, wherein the joining layer comprises an adhesive having a number average molecular weight between about 1,000 and 300,000 g/mol.

16. The method of claim 14, wherein the joining layer further comprises a reactive diluent in an amount between about 10% and about 70% by weight.

17. The method of claim 14, wherein the joining layer further comprises a photoinitiator in an amount between about 0.5% and about 5% by weight.

18. The method of claim 14, further comprising the step of dicing the ground substrate into a plurality of ground substrates.

19. The method of claim 14, wherein the substrate to be ground comprises a semiconductor wafer, the wafer having a circuit face adjacent said joining layer and a non-circuit face.

20. The method of claim 14, wherein the curable acrylate adhesion modifying agent includes silicone polymers substituted with (meth)acrylate groups.
